(19) United States
(12) Patent Application Publication
(10) Pub. No.: US 2007/0210354 A1
(43) Pub. Date: Sep. 13, 2007

(54) Semiconductor device and semiconductor device manufacturing method

(75) Inventors: Toshihide Nabatame, Tokyo (JP); Masaru Kadoshima, Tokyo (JP)

Correspondence Address: Stanley P. Fisher;Reed Smith LLP, Suite 1400, 3110 Fairview Park Drive, Falls Church, VA, 22042-4503, US

(73) Assignee: Renesas Technology Corp.

(21) Appl. No.: 11/713,627

(22) Filed: Mar. 5, 2007

(30) Foreign Application Priority Data
Mar. 10, 2006 (JP) JP2006-65674

(51) Int. Cl. H01L 29/76

(52) U.S. Cl. 257/288

(57) ABSTRACT

Provided is a technology capable of improving the productivity of a p channel MISFET using a high dielectric-constant film as a gate insulating film and a conductive film containing metal as a gate electrode. In this technology, a threshold voltage of the p channel MISFET can be decreased even if a work function value of the conductive film containing metal at the time of contacting a silicon oxide film is away from a value near a valence band of silicon. A p channel MISFET formed on a semiconductor substrate has a gate insulating film formed of a hafnium oxide film, a metal oxide film formed of an aluminum oxide film on this gate insulating film, and a gate electrode formed of a tantalum nitride film on this metal oxide film. The metal oxide film has a function to shift a work function value of the gate electrode.

### CROSS-REFERENCE TO RELATED APPLICATION

The present application claims priority from Japanese Patent Application No. JP 2006-65674 filed on Mar. 10, 2006, the content of which is hereby incorporated by reference into this application.

### TECHNICAL FIELD OF THE INVENTION

The present invention relates to semiconductor devices and semiconductor device manufacturing technologies. In particular, it relates to a technology effectively applied to a MISFET (Metal Insulator Semiconductor Field Effect Transistor) using a conductive film containing metal for a gate electrode.

### BACKGROUND OF THE INVENTION

Japanese Patent Application Laid-Open Publication No. 2005-294422 (Patent Document 1) discloses a technology capable of, when metal is used for the gate electrode material of a MISFET, preventing reaction or exfoliation between metal and a gate insulating film and controlling a threshold voltage of the MISFET.

Specifically, the MISFET includes a gate insulating film formed on a semiconductor substrate and a gate electrode formed on the gate insulating film and made of a material (for example, a tantalum nitride film) containing a first metal (for example, tantalum). Also, the gate insulating film includes a first insulator (for example, a silicon oxide film) and a second insulator (for example, a tantalum oxide film), and the second insulator is an oxide layer of a second metal of the same type as the first metal.

### SUMMARY OF THE INVENTION

Conventionally, in view of a high insulation resistance and an excellent electrical and physical stability at an interface between silicon and silicon oxide, a silicon oxide film has been used for the gate insulating film. However, with the development in microfabrication of devices, demands for extremely reducing the film thickness of the gate insulating film have been increasing. If such a thin silicon oxide film is used for the gate insulating film, however, electrons flowing in the channel of the MISFET tunnel through a barrier wall formed of the silicon oxide film into the gate electrode, that is, a so-called tunnel current occurs.

To get around this problem, by the use of a material with a dielectric constant higher than that of the silicon oxide film, a high dielectric-constant film having an increased physical film thickness even with the same capacity has been used. Since the physical film thickness can be increased even with the same capacity when using such a high dielectric-constant film, it is possible to reduce the leakage current.

On the other hand, conventionally, a polysilicon film has been used as the material of the gate electrode. However, in recent years, with the development in microfabrication of MISFETs, the thickness of the gate insulating film has been more and more reduced, and depletion of the gate electrode when a polysilicon film is used for the gate electrode has become nonnegligible. More specifically, although it becomes necessary to reduce the thickness of the gate insulating film because of the microfabrication, due to the depletion of the gate electrode, the parasitic capacitance occurring in the gate electrode becomes nonnegligible. For this reason, the use of a conductive film containing metal as a material of the gate electrode instead of a polysilicon film has been considered. The conductive film in this specification means a conductive film containing metal, which includes a metal film or a metal compound film with conductivity.

When a conductive film containing metal is used as the gate electrode material, first of all, it is conceivable that the same conductive film is used for the gate electrodes of both of an n channel MISFET and a p channel MISFET.

However, if the same conductive film is used for the gate electrodes of both of an n channel MISFET and a p channel MISFET, since the work function of the conductive film for use determines the threshold voltage of the MISFETs, there is a problem that the threshold voltage of either one of the n channel MISFET and the p channel MISFET will be high. More specifically, since the work function value which decreases the threshold voltage of the n channel MISFET is different from the work function value which decreases the threshold voltage of the p channel MISFET, if a conductive film with a work function which decreases the threshold voltage of either one of the MISFETs is selected, the threshold voltage of the other MISFET is increased.

In the n channel MISFET, if the work function of the gate electrode material has a value near a conduction band of silicon (about 4.05 eV), the threshold voltage of the n channel MISFET can be decreased. On the other hand, in the p channel MISFET, if the work function of the gate electrode material has a value near a valence band of silicon (about 5.15 eV), the threshold voltage of the p channel MISFET can be decreased. Therefore, conductive films with different work function values are used for gate electrodes of the n channel MISFET and the p channel MISFET.

For example, for the gate electrode of the p channel MISFET, the use of precious metal with its work function value of about 5 eV such as an Ru film, a Pt film, an Ir film, an RuO₂ film, and an IrO₂ film has been often considered.

However, when such a precious metal as described above is used for the gate electrode, process dependency is very large due to an etching resistant property of precious metal and a property that the work function value is significantly changed by oxidization as typified by Ru, and there is a large problem in productivity. Moreover, since a volume of, for example, an Ru film is expanded when oxidized, a problem of exfoliation between the gate electrode and the gate insulating film occurs probably.

On the other hand, as a material with an excellent thermal stability and easily applicable to a process of a semiconductor substrate made of silicon, a TaN film is known. However, since the TaN film has a work function value of about 4.6 eV, if it is used for the gate electrode of a p channel MISFET, there is a problem that the threshold voltage cannot be sufficiently decreased.

An object of the present invention is to provide a technology capable of achieving an improvement in productivity of a p channel MISFET in which a high dielectric-constant film is used for the gate insulating film and a conductive film containing metal is used for the gate electrode. Also, another object of the present invention to provide a technology capable of decreasing a threshold voltage of the p channel MISFET even if a work function value of the conductive film containing metal at the time of contacting a silicon oxide film is away from a value near a valence band of silicon.

The above and other objects and novel characteristics of the present invention will be apparent from the description of this specification and the accompanying drawings.

The typical ones of the inventions disclosed in this application will be briefly described as follows.

A semiconductor device according to the present invention relates to a semiconductor device having a p channel MISFET in a first region of a semiconductor substrate and an n channel MISFET in a second region of the semiconductor substrate. In this semiconductor device, the p channel MISFET comprises: (a) a gate insulating film which is formed on the semiconductor substrate and is formed of a high dielectric-constant film with a dielectric constant higher than that of a silicon oxide film; (b) an insulating metal oxide film which is formed on the gate insulating film and generates a dipole; and (c) a gate electrode which is formed on the metal oxide film.

Also, the semiconductor device manufacturing method according to the present invention relates to a semiconductor device manufacturing method in which a p channel MISFET is formed in a first region of a semiconductor substrate and an n channel MISFET is formed in a second region of the semiconductor substrate. This method comprises the steps of: (a) forming a high dielectric-constant film with a dielectric constant higher than that of a silicon oxide film in the first region and the second region of the semiconductor substrate; (b) forming a second conductive film containing metal on the high dielectric-constant film formed in the first region and the second region; and (c) removing the second conductive film formed in the first region. Further, it comprises the steps of; (d) forming an insulating metal oxide film in the first region and the second region; (e) performing a heat treatment to the semiconductor substrate; and (f) forming a first conductive film containing metal on the metal oxide film formed in the first region and the second region. Furthermore, it comprises the step of; (g) removing the metal oxide film and the first conductive film formed in the second region and processing the high dielectric-constant film, the metal oxide film, and the first conductive film formed in the first region, thereby forming a first gate insulating film made of the high dielectric-constant film and a first gate electrode made of the first conductive film in the first region. Furthermore, it also comprises the step of; (h) processing the high dielectric-constant film and the second conductive film formed in the second region, thereby forming a second gate insulating film made of the high dielectric-constant film and a second gate electrode made of the second conductive film in the second region.

The effects obtained by typical aspects of the present invention will be briefly described below.

In a p channel MISFET using a high dielectric-constant film for the gate insulating film and a conductive film containing metal for the gate electrode, a high-quality conductive film formed through a semiconductor process can be used for the gate electrode. Therefore, productivity can be increased. Also, an insulating metal oxide film is formed between the gate insulating film and the gate electrode, thereby forming a dipole between the gate electrode and the metal oxide film. Therefore, the threshold voltage of the p channel MISFET can be decreased even if a work function value of the conductive film containing metal at the time of contacting a silicon oxide film is away from a value near a valence band of silicon.

### BRIEF DESCRIPTIONS OF THE DRAWINGS

FIG. 1 is a sectional view showing the structure of a semiconductor device according to an embodiment of the present invention;

FIG. 2 is a graph showing a relation between a work function on a silicon oxide film and a work function on a hafnium oxide film or an aluminum oxide film;

FIG. 3 is a band diagram in the case where a gate insulating film and a gate electrode are brought into contact with each other;

FIG. 4 is a band diagram in the case where an aluminum oxide film is formed between the gate insulating film and the gate electrode;

FIG. 5 is a band diagram in the case where a hafnium oxide film is formed between the gate insulating film and the gate electrode;

FIG. 6 is a graph showing a relation between a gate voltage and mobility of carriers when a silicon oxide film, a hafnium oxide film, or a aluminum oxide film is used for a gate insulating film;

FIG. 7 is a graph showing a relation between a film thickness of the aluminum oxide film and an amount of shift of the work function;

FIG. 8 is a sectional view showing a semiconductor device manufacturing process according to the embodiment;

FIG. 9 is a sectional view showing the semiconductor device manufacturing process continued from FIG. 8;

FIG. 10 is a sectional view showing the semiconductor device manufacturing process continued from FIG. 9;

FIG. 11 is a sectional view showing the semiconductor device manufacturing process continued from FIG. 10;

FIG. 12 is a sectional view showing the semiconductor device manufacturing process continued from FIG. 11;

FIG. 13 is a sectional view showing the semiconductor device manufacturing process continued from FIG. 12;

FIG. 14 is a sectional view showing the semiconductor device manufacturing process continued from FIG. 13;

FIG. 15 is a sectional view showing the semiconductor device manufacturing process continued from FIG. 14;

FIG. 16 is a sectional view showing the semiconductor device manufacturing process continued from FIG. 15;

FIG. 17 is a sectional view showing the semiconductor device manufacturing process continued from FIG. 16; and

FIG. 18 is a sectional view showing the semiconductor device manufacturing process continued from FIG. 17.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Also, components having the same function are denoted by the same reference symbols throughout the drawings for describing the embodiment, and the repetitive description thereof will be omitted.

An embodiment of the present invention will be described in detail below based on the drawings. A conductive film in this specification means a conductive film containing metal, which includes a metal film or a metal compound film with conductivity.

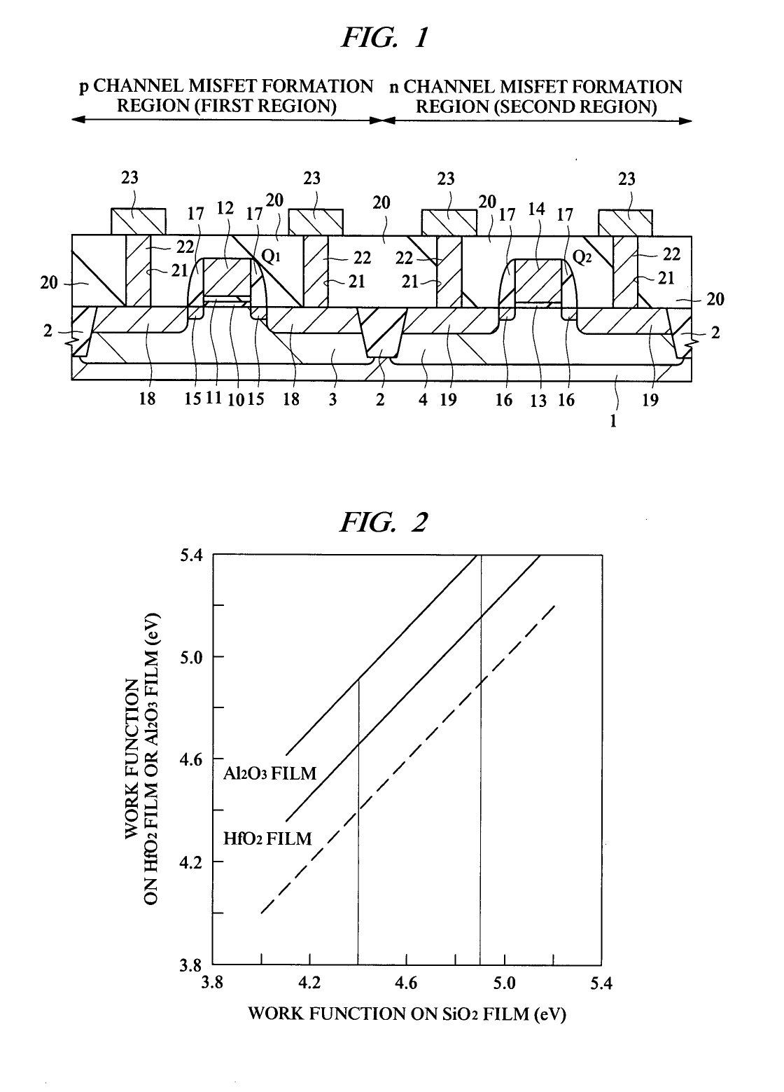

FIG. 1 is a sectional view showing a structure of a semiconductor device according to an embodiment of the present invention. In FIG. 1, a semiconductor substrate 1 has a p channel MISFET formation region (first region) and an n channel MISFET formation region (second region), and a p channel MISFET Q₁ is formed in the p channel MISFET formation region and an n channel MISFET Q₂ is formed in the n channel MISFET formation region.

In a main surface of the semiconductor substrate 1, an element isolation region 2 is formed. The element isolation region 2 has a function to prevent interference between elements formed on the semiconductor substrate 1. For example, the element isolation region 2 is formed through STI (Shallow Trench Isolation) process, in which a trench is formed in the semiconductor substrate 1 and a silicon oxide film is then buried in this trench. Active regions isolated by this element isolation region 2 are the p channel MISFET formation region and the n channel MISFET formation region.

An n well 3 which is a semiconductor region is formed in the semiconductor substrate 1 in the p channel MISFET formation region, and a p well 4 which is a semiconductor region is formed in the semiconductor substrate 1 in the n channel MISFET formation region. In the n well 3, n type impurities such as phosphorus (P) or arsenic (As) are introduced. In the p well 4, p type impurities such as boron (B) are introduced.

Next, the structure of the p channel MISFET formed in the p channel MISFET formation region will be described. As shown in FIG. 1, a gate insulating film (first gate insulating film) 10 is formed on the n well 3 formed in the semiconductor substrate 1 in the p channel MISFET formation region.

This gate insulating film 10 is formed of, for example, a high dielectric-constant film with a dielectric constant higher than that of a silicon oxide film. Conventionally, in view of a high insulation resistance and an excellent electrical and physical stability at an interface between silicon and silicon oxide, a silicon oxide film has been used for the gate insulating film 10. However, with the development in microfabrication of devices, demands for extremely reducing the film thickness of the gate insulating film 10 have been increasing. If such a thin silicon oxide film is used for the gate insulating film 10, however, electrons flowing in the channel of the MISFET tunnel through a barrier wall formed of the silicon oxide film into the gate electrode, that is, a so-called tunnel current occurs.

To get around this problem, by the use of a material with a dielectric constant higher than that of the silicon oxide film, a high dielectric film having an increased physical film thickness even with the same capacity has been used. Since the physical film thickness can be increased even with the same capacity when using such a high dielectric film, it is possible to reduce the leakage current.

For example, a hafnium oxide film (HfO₂ film), which is one of hafnium oxides, is used as the high dielectric film. In place of a hafnium oxide film, other hafnium-based insulating films such as a hafnium aluminate film, an HfON film (hafnium oxynitride film), an HfSiO film (hafnium silicate film), an HfSiON film (hafnium silicon oxynitride film), and an HfAlO film can be used. Furthermore, hafnium-based insulating films obtained by introducing an oxide such as tantalum oxide, niobium oxide, titanium oxide, zirconium oxide, lanthanum oxide, or yttrium oxide into any of the above-mentioned hafnium-based insulating films can be used. Similar to the hafnium oxide film, the hafnium-based insulating film has a dielectric constant higher than that of a silicon oxide film or a silicon oxynitride film. Therefore, effects similar to those in the case of using the hafnium oxide film can be achieved. Also, as a high dielectric film, an aluminum oxide film or an aluminum oxynitride film can be used.

On the gate insulating film 10, an insulating metal oxide film 11 is formed. The metal oxide film 11 is formed of, for example, an aluminum oxide film (Al₂O₃ film). Although an aluminum oxide film is used for this metal oxide film 11 in this example, this is not meant to be restrictive, and the metal oxide film 11 may be formed of a film such as a tantalum oxide film, a titanium oxide film, a lanthanum oxide film, or a rare-earth oxide film. A feature of the present embodiment is to provide the metal oxide film 11. As described further below, since the metal oxide film 11 is provided, the work function value of a conductive film used for a gate electrode 12 can be increased. By this function, the work function value of the conductive film used for the gate electrode 12 can be set to a value near a valence band of silicon, thereby decreasing a threshold voltage of the p channel MISFET Q₁. Accordingly, the p channel MISFET Q₁ with low power consumption can be formed.

The gate electrode (first gate electrode) 12 is formed on the metal oxide film 11. The gate electrode 12 is formed of, for example, a tantrum nitride film (TaN film). However, this is not meant to be restrictive, and the gate electrode 12 can be formed of any of a TiN film, a TaSiN film, a TiAlN film, a HfN film, an NiₓSi₁₋ₓ film, a PtSi film, an NiₓTa₁₋ₓSi film, an NiₓPt₁₋ₓSi film, an HfSi film, a WSi film, an IrₓSi₁₋ₓ film, a TaGe film, a TaCₓ film, an Mo film, and a W film. For example, a tantalum nitride film is a material excellent in thermal stability and easily applicable to a process of a semiconductor substrate made of silicon. Therefore, by using a tantalum nitride film for the gate electrode 12, the productivity improvement can be achieved. On the other hand, the tantalum nitride film has a work function value of 4.6 eV when a silicon oxide film is used for the gate insulating film 10. Therefore, when the tantalum nitride film is used for the gate electrode 12 of the p channel MISFET Q₁, the work function value is away from a value near the valence band of silicon (5.15 eV), and therefore, the threshold voltage of the p channel MISFET Q₁ cannot be decreased. To get around this, in the present embodiment, the metal oxide film 11 is provided between the gate insulating film 10 and the gate electrode 12. By providing the metal oxide film 11 in this manner, the effective work function value of the tantalum nitride film is increased to be a value near the valence band of silicon. Accordingly, it is possible to decrease the threshold voltage of the p channel MISFET Q₁. That is, by providing the metal oxide film 11, the threshold voltage can be decreased while using a tantalum nitride film with high thermal stability capable of increasing the productivity as the material of the gate electrode 12.

On both sides of the gate electrode 12, sidewalls 17 made of, for example, a silicon oxide film are formed. In the semiconductor substrate 1 directly below these sidewalls 17, low-concentration p type impurity diffusion regions 15, which are semiconductor regions, are formed. High-concentration p type impurity diffusion regions 18 are formed on the outer sides of the low-concentration p type impurity diffusion regions 15.

In the low-concentration p type impurity diffusion regions 15 and the high-concentration p type impurity diffusion regions 18, p type impurities such as boron are introduced. In the high-concentration p type impurity diffusion regions 18, p type impurities with a concentration higher than that of low-concentration p type impurity diffusion regions 15 are introduced. By these low-concentration p type impurity diffusion regions 15 and high-concentration p type impurity diffusion regions 18, a source region and a drain region of the p channel MISFET Q₁ having an LDD (Lightly Doped Drain) structure are formed. As described above, by constituting the source region and the drain region from the low-concentration p type impurity diffusion regions 15 and the high-concentration p type impurity diffusion regions 18, the electric field concentration below an end of the gate electrode 12 can be prevented.

Next, the structure of the n channel MISFET Q₂ formed in the n channel MISFET formation region will be described. As shown in FIG. 1, the n channel MISFET Q₂ has a gate insulating film (second gate insulating film) 13 on the p well 4 formed in the semiconductor substrate 1. This gate insulating film 13 is also formed of a high dielectric-constant film with a dielectric constant higher than that of a silicon oxide film.

A gate electrode 14 is formed on the gate insulating film 13. The gate electrode 14 is formed of a film such as an Hf film, a Ta film, an Mn film, a Y film, an La film, an Ln film, a YbSi film, a TaSi film, an ErSi film, an NiₓYb₁₋ₓSi film, or an ErGe film. Since any of these films have the work function value near a conduction band of silicon (4.05 eV), the threshold voltage of the n channel MISFET Q₂ can be decreased.

On both sides of the gate electrode 14, the sidewalls 17 made of, for example, a silicon oxide film are formed. In the semiconductor substrate 1 directly below these sidewalls 17, low-concentration n type impurity diffusion regions 16, which are semiconductor regions, are formed. High-concentration n type impurity diffusion regions 19 are formed on the outer sides of the low-concentration n type impurity diffusion regions 16.

In the low-concentration n type impurity diffusion regions 16 and the high-concentration n type impurity diffusion regions 19, n type impurities such as phosphorus and arsenic are introduced. In the high-concentration n type impurity diffusion regions 19, n type impurities with a concentration higher than that of low-concentration n type impurity diffusion regions 16 are introduced. By these low-concentration n type impurity diffusion regions 16 and high-concentration n type impurity diffusion regions 19, a source region and a drain region of the n channel MISFET Q₂ having an LDD structure are formed. As described above, by constituting the source region and the drain region from the low-concentration n type impurity diffusion regions 16 and the high-concentration n type impurity diffusion regions 19, the electric field concentration below an end of the gate electrode 14 can be prevented.

The semiconductor device according to the present embodiment is configured in a manner described above, and features of the present invention will be described below. One of the features of the present invention is to form a metal oxide film between the gate insulating film and the gate electrode in the p channel MISFET Q₁.

FIG. 2 is a graph showing a relation between a work function value of the gate electrode 12 when a silicon oxide film (SiO₂ film) is used for the gate insulating film and a work function value of the gate electrode when a hafnium oxide film (HfO₂ film) or an aluminum oxide film (Al₂O₃ film) is used for the gate insulating film.

In FIG. 2, the horizontal axis represents a work function value when the gate electrode is formed on the silicon oxide film, and the vertical axis represents a work function value when the gate electrode is formed on a hafnium oxide film or an aluminum oxide film. A broken line in FIG. 2 represents a case where the work function value on the silicon oxide film and the work function value on the hafnium oxide film or the aluminum oxide film are equal to each other. Actually, the work function value on the silicon oxide film and the work function value on the hafnium oxide film or the aluminum oxide film are different from each other, which is represented by a solid line.

For example, it is assumed that a tantalum nitride film is used for the gate electrode. When a tantalum nitride film is used for the gate electrode and a silicon oxide film is used for the gate insulating film in contact with this gate electrode, the effective work function value of the tantalum nitride film is 4.6 eV. At this time, if the gate insulating film is replaced by a hafnium oxide film, the effective work function value of the tantalum nitride film is 4.8 eV. More specifically, a point where a line from a point of 4.6 eV on the horizontal axis and a solid line indicating a hafnium oxide film cross has a value of 4.8 eV on the vertical axis. This indicates that, when a hafnium oxide film is used for the gate insulating film and a tantalum nitride film configuring a gate electrode is formed on this hafnium oxide film, the effective work function value of the tantalum nitride film is increased by 0.2 eV in comparison with the case of using a silicon oxide film for the gate insulating film. Therefore, when a tantalum nitride film is used, by replacing the gate insulating film from a silicon oxide film to a hafnium oxide film, it is possible to increase the effective work function value of the tantalum nitride film.

However, even when a hafnium oxide film is used for the gate insulating film, the effective work function value of the tantalum nitride film is 4.8 eV, which is away from the value near the valence band of silicon (5.15 eV) at which the threshold voltage can be sufficiently reduced. Therefore, even when a gate electrode made of a tantalum nitride film is formed on the gate insulating film made of hafnium oxide, the threshold voltage of the p channel MISFET cannot be sufficiently decreased.

Here, as shown in FIG. 2, when an aluminum oxide film is used for the gate insulating film, the effective work function value of the tantalum nitride film is about 5.1 eV. More specifically, it can be understood that, when the tantalum nitride film is brought into contact with the aluminum oxide film, the effective work function value takes a value near the valence band of silicon. Thus, in the present embodiment, an aluminum oxide film is formed as a metal oxide film on the gate insulating film made of a hafnium oxide film, and a tantalum nitride film forming a gate electrode is brought into contact with the aluminum oxide film. By this means, the effective work function value of the tantalum nitride film forming a gate electrode can be set to a value near the valence band of silicon. In other words, by forming a metal oxide film made of an aluminum oxide film between the gate insulating film made of a hafnium oxide film and the gate electrode made of a tantalum nitride film, the threshold voltage of the p channel MISFET can be decreased, thereby achieving the low power consumption. More specifically, since the work function value of the gate electrode when a metal oxide film is formed is higher than the work function value when the gate electrode is formed on the gate insulating film without forming the metal oxide film, the threshold voltage of the p channel MISFET can be decreased.

In FIG. 2, the cases of the hafnium oxide film and the aluminum oxide film are shown as examples of the metal oxide film. However, in general, the effective work function value when a conductive film containing metal is formed on a metal oxide film is higher than the effective work function value when a conductive film containing metal is formed on a silicon oxide film. Therefore, by forming various types of metal oxide films between the gate insulating film and the gate electrode, even if a conductive film with an effective work function value of 4.4 eV to 4.9 eV at the time of contacting a silicon oxide film is used, the work function value of the conductive film can be adjusted to a value near valence band of silicon, and the threshold voltage of the p channel MISFET can be decreased. Examples of metal oxide films include, in addition to a hafnium oxide film and an aluminum oxide film, a tantalum oxide film, a titanium oxide film, a lanthanum oxide film, and a rare-earth oxide film.

As shown in FIG. 2, it can be understood that the amount of shift of the effective work function value is different depending on the type of the metal oxide film. In the present embodiment, the case of using a tantalum nitride film as the material of the gate electrode is described. In the case of using the tantalum nitride film, an aluminum oxide film is used as the metal oxide film to be brought into contact. By this means, the effective work function value can be set to a value near the valence band of silicon. In other words, an aluminum oxide film can be used as a metal oxide film which has a function to shift the work function value of the tantalum nitride film from 4.6 eV to 5.1 eV. Thus, when another conductive film with a work function value of 4.4 eV to 4.9 eV at the time of contacting the silicon oxide film is used, for example, a metal oxide film other than the aluminum oxide film is selected, thereby adjusting the effective work function value of the conductive film to a value near the valence band of silicon. For example, in FIG. 2, when a conductive film with a work function value of 4.9 eV at the time of contacting the silicon oxide film is used for the gate electrode, if an aluminum oxide film is used as a metal oxide film to be formed between the gate insulating film and the gate electrode, the effective work function value of the conductive film is excessively increased. By contrast, if a hafnium oxide film is selected as a metal oxide film, the effective work function value of the conductive film can be adjusted to a value near the valence band of silicon (5.1 eV). Therefore, for example, when a conductive film with a work function value of 4.9 eV at the time of contacting the silicon oxide film is used for the gate electrode, a hafnium oxide film can be used as a metal oxide film.

As described above, in the present embodiment, a thermally-stable conductive film which is easily applicable to a semiconductor process and has a work function value of 4.4 eV to 4.9 eV at the time of contacting the silicon oxide film can be used for the gate electrode of the p channel MISFET. More specifically, by forming an optimum metal oxide film between the gate insulating film and the gate electrode, the effective work function value can be increased. Therefore, even if the above-described conductive film is used, the threshold voltage can be decreased.

In view of the fact that the threshold voltage can be decreased if the work function value is near the valence band of silicon, the use of precious metal with a work function value of about 5 eV such as an Ru film, a Pt film, an Ir film, an RuO₂ film, or an IrO₂ film for the gate electrode of the p channel MISFET has been often considered.

However, when such a precious metal as described above is used for the gate electrode, process dependency is very large due to an etching resistant property of precious metal and a property that the work function value is significantly changed by oxidization as typified by Ru, and there is a large problem in productivity. More specifically, the above-mentioned precious metals are desirable materials from the viewpoint that they have the work function value near the valence band of silicon, but they have a problem in productivity such as an etching resistant property.

To get around this problem, in the present embodiment, the material to be used for the gate electrode of the p channel MISFET is selected under the condition that it is a thermally-stable material and easily applicable to a semiconductor process as typified by a tantalum nitride film. However, since the above-mentioned materials, for example, a tantalum nitride film have the work function value at the time of contacting the silicon oxide film of 4.4 eV to 4.9 eV in many cases, they are not desirable in view of decreasing the threshold voltage.

However, in the present embodiment, by forming a metal oxide film between the gate insulating film and the gate electrode, the effective work function value of the conductive film with a work function value of 4.4 eV to 4.9 eV at the time of contacting the silicon oxide film can be shifted to a value near the valence band of silicon (5.15 eV). By this means, a decrease in threshold voltage of the p channel MISFET is achieved.

More specifically, in the present embodiment, it is possible to achieve significant effects of the use of a thermally-stable material applicable to a semiconductor process and the reduction of the threshold voltage of the p channel MISFET at the same time.

Next, the mechanism capable of shifting the effective work function value in a direction of decreasing the threshold voltage by forming a metal oxide film between the gate insulating film and the gate electrode will be described with reference to the drawings. Note that, in the following description, the case of using a silicon oxide film for the gate insulating film is described. However, the mechanism can also be applied to the case of using a high dielectric-constant film such as a hafnium oxide film for the gate insulating film.

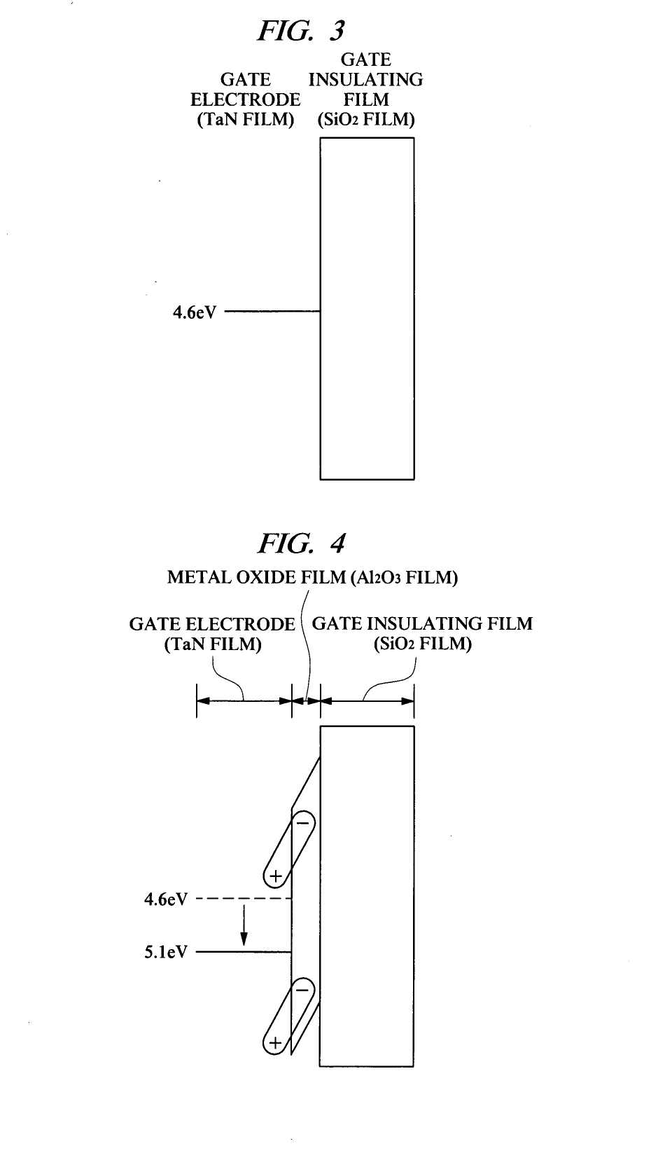

FIG. 3 is a band diagram in the case where a silicon oxide film is used for the gate insulating film and a tantalum nitride film is used for the gate electrode in contact with the gate insulating film. At this time, it can be understood that the work function value of the tantalum nitride film forming the gate electrode is 4.6 eV. Next, FIG. 4 is a band diagram in the case where an aluminum oxide film is formed as a metal oxide film between the gate insulating film and the gate electrode. In this case, a dipole (electric dipole) is formed at the boundary between the aluminum oxide film which is a metal oxide film and the tantalum nitride film which is a gate electrode. This dipole is formed so as to have an orientation that a negative pole is present in the aluminum oxide film and a positive pole is present in the tantalum nitride film. When the dipole with the above-described orientation is formed, energy on the positive pole side is lower in electronic energy than energy on the negative pole side. Therefore, the band of the aluminum oxide film is bent so that the boundary between the aluminum oxide film and the tantalum nitride film is lower than the boundary between the silicon oxide film and the aluminum oxide film. By this bending of the band, the effective work function value of the tantalum nitride film forming the gate electrode is shifted in an increasing direction. More specifically, in the case where an aluminum oxide film is used as a metal oxide film, the work function value is shifted from 4.6 eV to 5.1 eV. In this manner, when a metal oxide film is formed between the gate insulating film and the gate electrode, a dipole is formed at the boundary between the metal oxide film and the gate electrode. This dipole is formed so as to have an orientation that a negative pole is present on the metal oxide film side and a positive pole is present on the gate electrode side. Therefore, the band forming the metal oxide film is bent in a direction of increasing the effective work function value of the gate electrode, and the effective work function value of the gate electrode is shifted. Note that, as described above, when the gate electrode and the metal oxide film are brought into contact with each other, a dipole is formed at their boundary. In this case, an expression that “a dipole is generated at the metal oxide film” will be used in this specification. More specifically, “a dipole is generated at the metal oxide film” means that a dipole is formed at the boundary between the metal oxide film and the gate electrode.

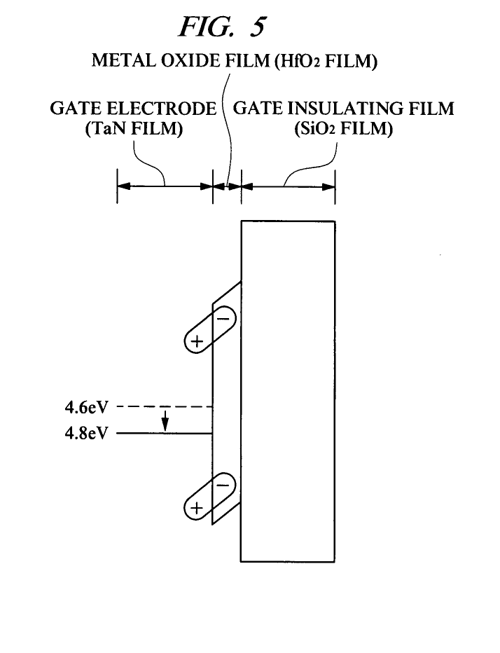

FIG. 5 is a band diagram in the case where a hafnium oxide film is used as a metal oxide film. As shown in FIG. 5, even when a hafnium oxide film is used as a metal oxide film, a dipole is formed at the boundary between the hafnium oxide film and the tantalum nitride film. At this time, similar to the case of FIG. 4, the dipole is formed so as to have an orientation that a negative pole is present on the hafnium oxide film side and a positive pole is present on the tantalum nitride film side. However, the degree of the bending of the band of the hafnium oxide film is milder compared with the case of the aluminum oxide film. Therefore, the amount of shift of the effective work function value of the tantalum nitride film is smaller compared with the case of the aluminum oxide film. For example, when a hafnium oxide film is used as a metal oxide film, the work function value is shifted from 4.6 eV to 4.8 eV.

Accordingly, the phenomenon of shifting the effective work function value of the gate electrode when a metal oxide film is formed between the gate insulating film and the gate electrode can be explained by the dipole which is generated at the boundary between the metal oxide film and the gate electrode.

Incidentally, in the p channel MISFET Q₁ in the present embodiment shown in FIG. 1, the gate insulating film 10 is formed of a high dielectric-constant film with a dielectric constant higher than that of a silicon oxide film, and the metal oxide film 11 made of an aluminum oxide film is formed on this gate insulating film 10. However, since the aluminum oxide film is also a high dielectric-constant film, it is also conceivable to form the gate insulating film 10 itself from an aluminum oxide film. Also in this case, since a tantalum nitride film is formed on the aluminum oxide film, similar to the case of FIG. 1, the effective work function value of the tantalum nitride film can be shifted and the threshold voltage of the p channel MISFET Q₁ can be decreased.

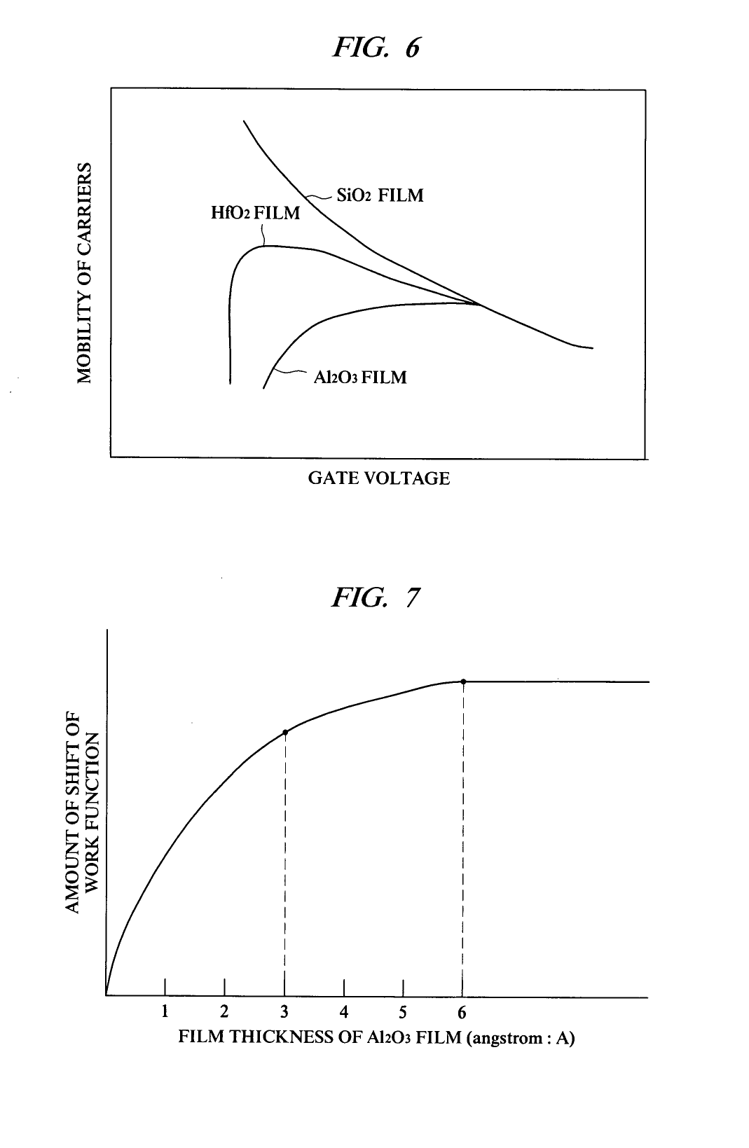

However, if the gate insulating film 10 is formed of an aluminum oxide film, the following problem occurs. This problem will be described with reference to FIG. 6. FIG. 6 is a graph showing a relation between a gate voltage applied to the gate electrode and mobility of carriers (electrons or positive holes). In a MISFET, by applying a voltage to the gate electrode, a channel is formed directly below the gate electrode, and an ON state is achieved by the carriers moving in this channel. At this time, if the mobility of the carriers is low, a problem occurs that it is difficult to acquire a sufficient current flowing in the MISFET even in an ON state. Note that, as shown in FIG. 6, the mobility of the carriers is significantly varied depending on the type of the gate insulating film. FIG. 6 shows a relation between the gate voltage and the mobility of the carriers when a silicon oxide film, a hafnium oxide film, or an aluminum oxide film is used for the gate insulating film. As is apparent from FIG. 6, the mobility of the carriers is the highest when a silicon oxide film is used for the gate insulating film, second highest when a hafnium oxide film is used, and is the lowest when an aluminum oxide film is used. Accordingly, it can be understood that the problem that the mobility of the carriers is deteriorated occurs when an aluminum oxide film is used for the gate insulating film.

From the reason as described above, in the present embodiment, it is desired that an aluminum oxide film is not used for the gate insulating film 10 itself. More specifically, for example, a hafnium oxide film is used for the gate insulating film 10 and an aluminum oxide film is laminated on this gate insulating film 10. According to this structure, since the film thickness of the aluminum oxide film can be reduced, it is possible to sufficiently suppress the deterioration in mobility of the carriers. On the other hand, since a tantalum nitride film forming the gate electrode is formed on the aluminum oxide film, a dipole can be generated at the boundary between the aluminum oxide film and the tantalum nitride film, and the effective work function value of the tantalum nitride film can be shifted to a value near the valence band of silicon. However, although the above-described inconvenience occurs when an aluminum oxide film is used for the gate insulating film 10 itself, since the aluminum oxide film itself is a high dielectric-constant film, an aluminum oxide film can be used as the gate insulating film 10 though not optimum.

Next, a relation between the film thickness of the metal oxide film and the amount of shift of the work function value of the conductive film forming the gate electrode will be described. FIG. 2 shows the metal oxide films and the effective work function values of the conductive film in contact with the metal oxide films. For example, it can be understood from FIG. 2 that the effective work function value of the conductive film is shifted more largely in the case of the aluminum oxide film than the case of the hafnium oxide film. In this case, the work function of each of the aluminum oxide film and the hafnium oxide film is represented by one straight line. In practice, however, the amount of shift of the effective work function value of the conductive film in contact with the metal oxide film is varied depending on the film thickness of the metal oxide film.

FIG. 7 shows a rate of change between the film thickness of the aluminum oxide film and the effective work function value of the conductive film in contact with the aluminum oxide film. The horizontal axis represents a film thickness (Angstrom: A) of the aluminum oxide film, and the vertical axis represents an amount of shift of the effective work function value of the conductive film. As shown in FIG. 7, it can be understood that, as the film thickness of the aluminum oxide film is increased from 0 to 6 A, the amount of shift of the effective work function value of the conductive film in contact with the aluminum oxide film is changed. This indicates that the amount of shift of the effective work function value of the conductive film in contact with the aluminum oxide film is changed depending on the film thickness of the aluminum oxide film. Also, when the film thickness of the aluminum oxide film exceeds a predetermined film thickness (for example, 6 A), the amount of shift of the effective work function value of the conductive film in contact with the aluminum oxide film becomes constant. For example, it can be understood that the amount of shift of the effective work function value when the film thickness of the aluminum oxide film is 3 A is smaller than the amount of shift of the effective work function value when the film thickness of the aluminum oxide film is equal to or larger than 6 A. In this case, if the film thickness of the aluminum oxide film is increased too much, the mobility of the carriers is significantly deteriorated as shown in FIG. 6, and therefore the film thickness cannot be increased so much. By contrast, if the film thickness of the aluminum oxide film is decreased too much, the amount of shift of the effective work function value of the conductive film in contact with the aluminum oxide film cannot be sufficiently acquired. Thus, for example, in FIG. 7, it can be said that the film thickness of the aluminum oxide film is desirably set about 3 A or more and 12 A or less.

As described above, by forming a metal oxide film between the gate insulating film and the gate electrode, the effective work function value of the gate electrode can be shifted in an increasing direction. First means to adjust the amount of shift at this time is to change the type of the metal oxide to be formed as shown in FIG. 2. Also, second means to adjust the amount of shift is to change the film thickness of the metal oxide film of the same type as shown in FIG. 7.

Next, a semiconductor device manufacturing method according to the present embodiment will be described with reference to the drawings.

First, as shown in FIG. 8, for example, the semiconductor substrate 1 in which p type impurities such as boron (B) are introduced to single-crystal silicon is prepared. Next, the element isolation regions 2 are formed in the main surface of the semiconductor substrate 1. The element isolation region 2 is formed of, for example, a silicon oxide film through STI (Shallow Trench Isolation) or LOCOS (Local Oxidization Of Silicon) process. FIG. 8 shows the element isolation region 2 formed through the STI process, in which a silicon oxide film is buried in a trench formed in the semiconductor substrate 1. Active regions are isolated by this element isolation region 2, and the p channel MISFET formation region (first region) and the n channel MISFET formation region (second region) are formed.

Subsequently, by using photolithography and ion implantation, the n well 3 is formed in the p channel MISFET formation region. The n well 3 is a semiconductor region, and n type impurities such as phosphorus or arsenic are introduced to the n well 3. Similarly, by using photolithography and ion implantation, the p well 4 is formed in the n channel MISFET formation region. The p well 4 is a semiconductor region, and p type impurities such as boron are introduced to the p well 4.

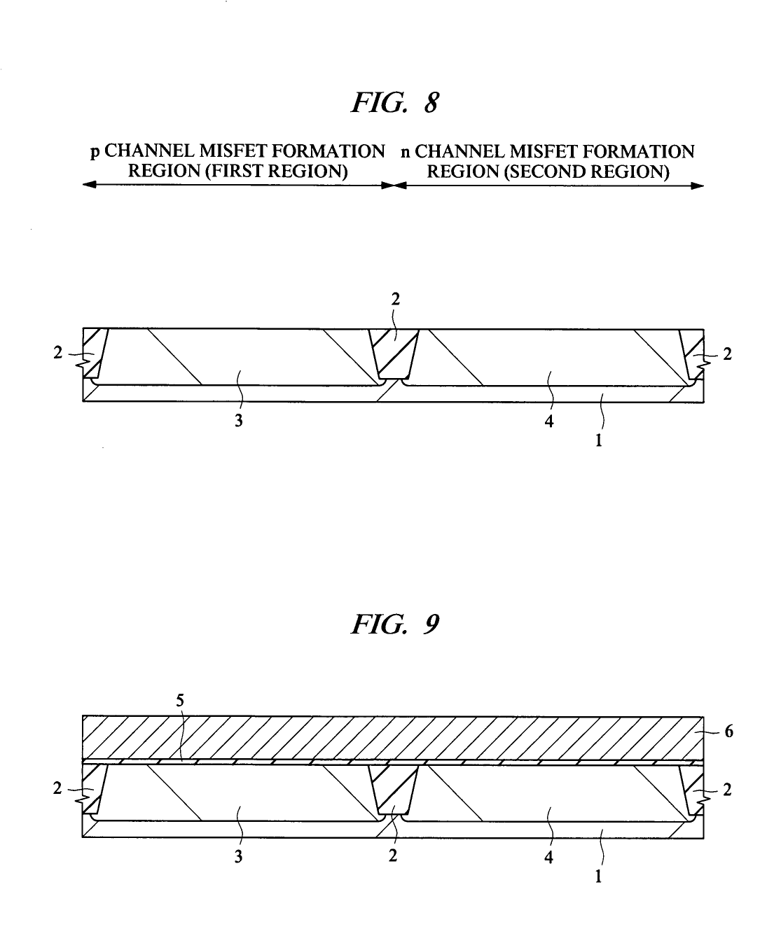

Next, as shown in FIG. 9, a hafnium oxide film (a high dielectric-constant film) 5 is formed on the main surface of the semiconductor substrate 1. The hafnium oxide film 5 can be formed by using, for example, a CVD or ALD (Atomic Layer Deposition). The hafnium oxide film 5 is a high dielectric-constant film with a dielectric constant higher than that of a silicon oxide film. Note that other hafnium-based insulating film such as a hafnium aluminate film, an HfON film, an HfSiO film, an HfSiON film, and an HfAlO film can be used in place of the hafnium oxide film 5. Then, on the hafnium oxide film 5, a tantalum silicide film (TaSi film) (second conductive film) 6 is formed. The tantalum silicide film 6 can be formed by the sputtering of target materials such as tantalum and silicon in an argon atmosphere. Note that any of an Hf film, a Ta film, an Mn film, a Y film, an La film, an Ln film, a YbSi film, a TaSi film, an ErSi film, an NiₓYb₁₋ₓSi film, and an ErGe film can be formed in place of the tantalum silicide film 6.

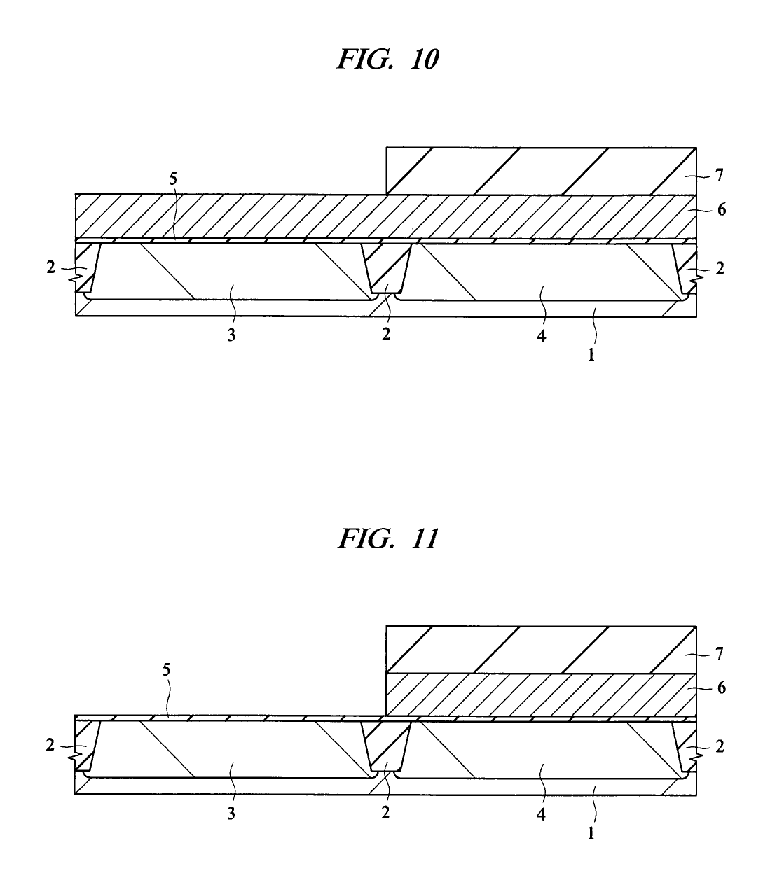

Next, as shown in FIG. 10, a resist film 7 is formed on the tantalum silicide film 6, and then, it is patterned through exposure and development processes. The patterning is performed so that the resist film 7 in the p channel MISFET formation region is removed and the resist film 7 in the n channel MISFET formation region is left.

Then, as shown in FIG. 11, through the etching with using the patterned resist film 7 as a mask, the tantalum silicide film 6 formed in the p channel MISFET formation region is removed. At this time, in the p channel MISFET formation region, the tantalum silicide film 6 is removed to expose the underlying hafnium oxide film 5. This hafnium oxide film 5 is damaged by the etching. Due to the damage by the etching, a lattice defect, an oxygen vacancy, and others are formed in the hafnium oxide film 5 exposed in the p channel MISFET formation region.

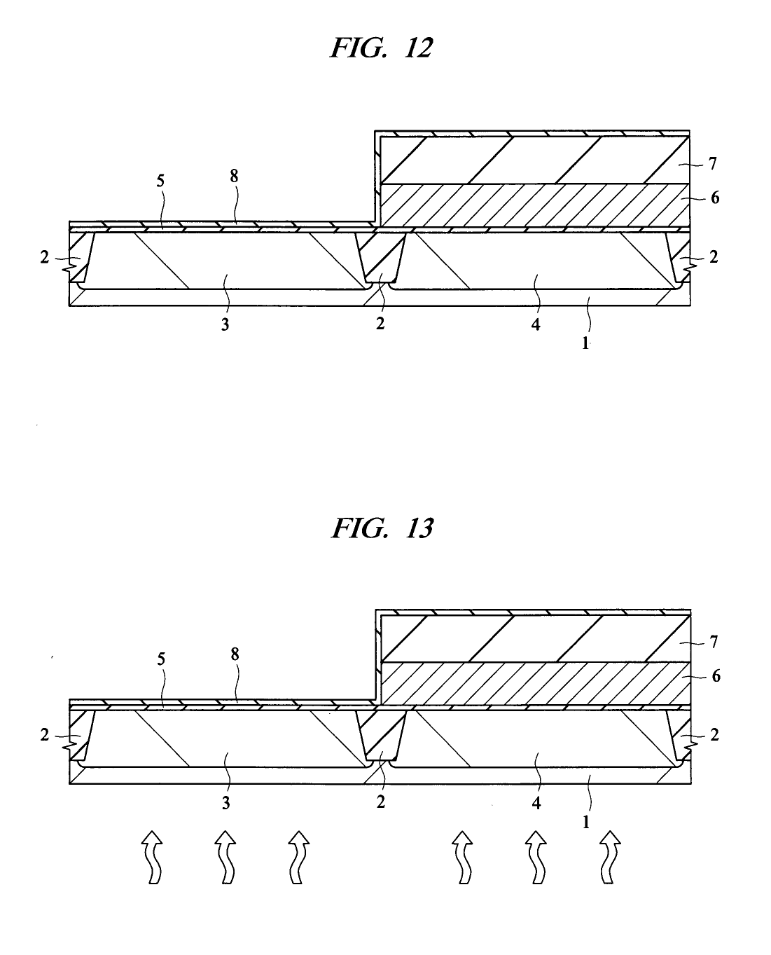

Next, as shown in FIG. 12, an aluminum oxide film (metal oxide film) 8 is formed on the semiconductor substrate 1. The aluminum oxide film 8 can be formed through, for example, the ALD process. In the ALD process, introduction of material gas, deposition of a film, and discharge of residual gas are performed as one cycle. The aluminum oxide film 8 of 1 A is formed per one cycle on the semiconductor substrate 1. However, with only one cycle, the aluminum oxide film 8 cannot be uniformly formed on the entire surface of the semiconductor substrate 1, but is formed in an island-like shape. Thus, in order to uniformly form the aluminum oxide film 8, the ALD process is performed for about three cycles, thereby forming the aluminum oxide film 8 having a film thickness of approximately 3 A on the semiconductor substrate 1. In this manner, by forming the aluminum oxide film 8 of approximately 3 A, the work function value of the tantalum nitride film to be formed in a subsequent process can be shifted to a value near the valence band of silicon. Note that other metal oxide film such as a tantalum oxide film, a titanium oxide film, a lanthanum oxide film, or a rare-earth oxide film can be formed in place of the aluminum oxide film 8.

Subsequently, as shown in FIG. 13, a heat treatment is performed to the semiconductor substrate 1. The heat treatment is performed at a temperature of, for example, 700° C. Through this heat treatment, the defects of the hafnium oxide film 5 formed in the p channel MISFET formation region can be repaired. That is, in the p channel MISFET formation region, the aluminum oxide film 8 is formed on the hafnium oxide film 5. If the heat treatment is performed in this state, oxygen atoms are supplied from the upper aluminum oxide film 8 to the underlying hafnium oxide film 5. Therefore, the defects in the hafnium oxide film 5 due to the etching damage are repaired by recombination of oxygen and others. By this means, reliability of the hafnium oxide film 5 formed in the p channel MISFET formation region can be improved. Furthermore, through the heat treatment, the quality of the aluminum oxide film 8 itself can be improved, and further, the surface of the aluminum oxide film 8 can be cleaned.

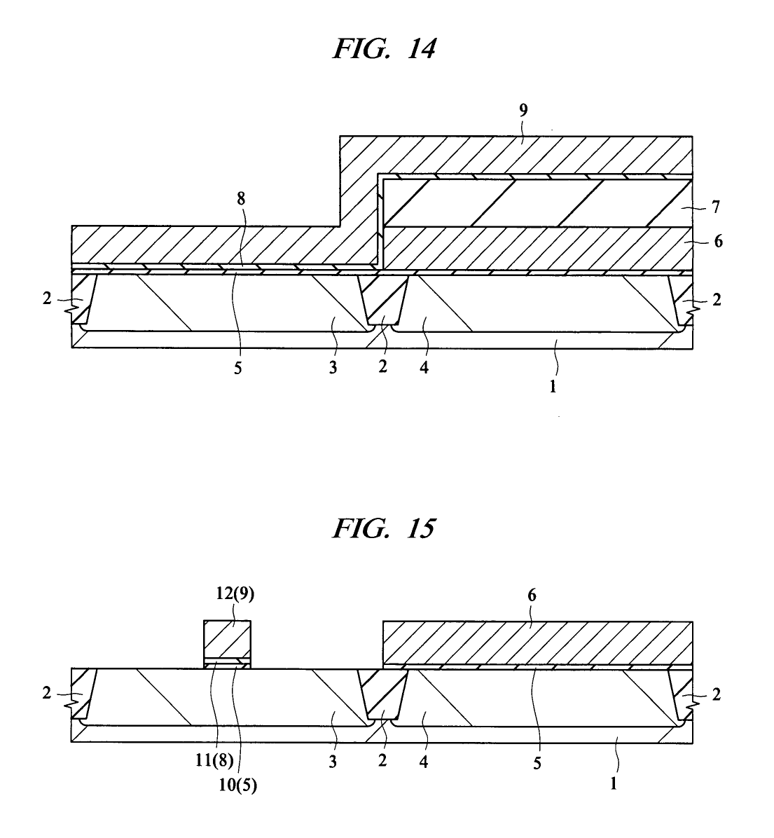

Next, as shown in FIG. 14, a tantalum nitride film (first conductive film) 9 is formed on the aluminum oxide film 8. The tantalum nitride film 9 can be formed through reactive sputtering of target materials such as tantalum in a mixed atmosphere of nitrogen gas and argon gas. Note that a film such as a TiN film, a TaSiN film, a TiAlN film, an HfN film, an NiₓSi₁₋ₓ film, a PtSi film, an NiₓTa₁₋ₓSi film, an NiₓPt₁₋ₓSi film, an HfSi film, a WSi film, an IrₓSi₁₋ₓ film, a TaGe film, a TaCₓ film, an Mo film, and a W film can be formed in place of the tantalum nitride film 9.

Next, as shown in FIG. 15, through the photolithography and etching processes, the gate electrode (first gate electrode) 12 is formed in the p channel MISFET formation region. At this time, the gate insulating film (first gate insulating film) 10 is formed below the gate electrode 12, and the metal oxide film 11 is formed between the gate insulating film 10 and the gate electrode 12. The gate insulating film 10 is formed of the hafnium oxide film 5, and the metal oxide film is formed of the aluminum oxide film 8. Furthermore, the gate electrode 12 is formed of the tantalum nitride film 9. Also, the resist film 7, the aluminum oxide film 8, and the tantalum nitride film 9 formed in the n channel MISFET formation region are removed by the lift-off each time when the resist film 7 is etched. Since the heat treatment as described above is performed to the gate insulating film 10, the defects thereof are repaired, and thus, reliability of the gate insulating film 10 can be improved.

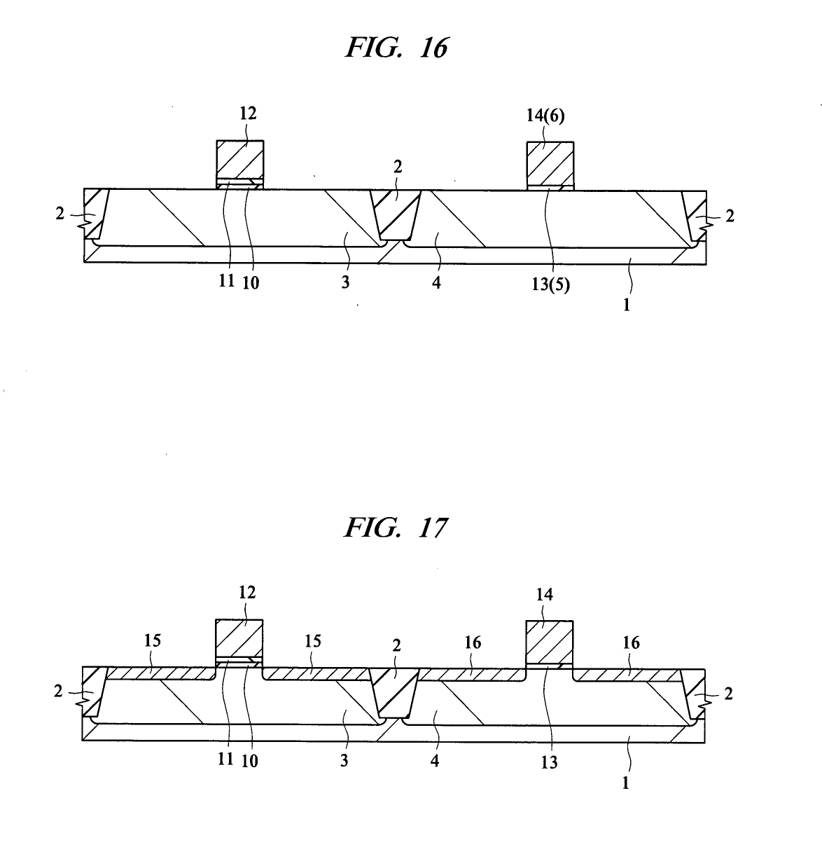

Next, as shown in FIG. 16, through the photolithography and etching processes, the gate insulating film (second gate insulating film) 13 and the gate electrode (second gate electrode) 14 are formed in the n channel MISFET formation region. The gate insulating film 13 is formed of the hafnium oxide film 5, and the gate electrode 14 is formed of the tantalum silicide film 6.

Thereafter, as shown in FIG. 17, through the photolithography and ion implantation processes, the low-concentration p type impurity diffusion regions 15 matched to the gate electrode 12 are formed. The low-concentration p type impurity diffusion regions 15 are semiconductor regions and can be formed by introducing p type impurities such as boron into the semiconductor substrate 1. Similarly, through the photolithography and ion implantation processes, the low-concentration n type impurity diffusion regions 16 matched to the gate electrode 14 are formed. The low-concentration n type impurity diffusion regions 16 are semiconductor regions and can be formed by introducing n type impurities such as phosphorus or arsenic into the semiconductor substrate 1.

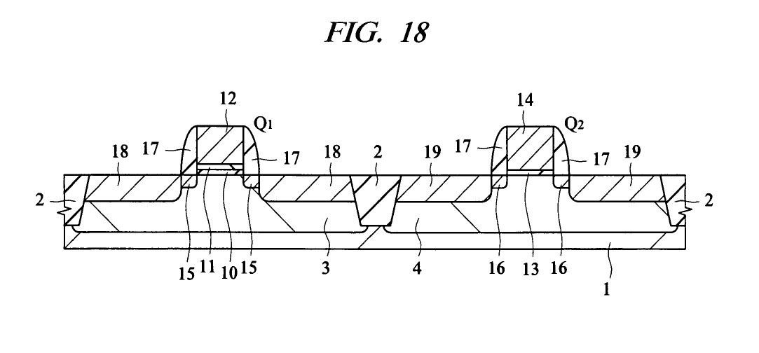

Next, as shown in FIG. 18, a silicon oxide film is formed on the semiconductor substrate 1, and anisotropic etching is performed to this silicon oxide film, thereby forming the sidewalls 17 on both sides of each of the gate electrodes 12 and 14. Then, through the photolithography and ion implantation processes, the high-concentration p type impurity diffusion regions 18 matched to the sidewalls 17 are formed. Similarly, through the photolithography and ion implantation processes, the high-concentration n type impurity diffusion regions 19 matched to the sidewalls 17 are formed. In this manner, the p channel MISFET Q₁ and the n channel MISFET Q₂ can be formed.

Next, a wiring process will be described. As shown in FIG. 1, a silicon oxide film 20 is formed on the main surface of the semiconductor substrate 1. This silicon oxide film 20 can be formed by, for example, the CVD. Thereafter, the surface of the silicon oxide film 20 is planarized by using, for example, CMP (Chemical Mechanical Polishing).

Next, through the photolithography and etching processes, contact holes 21 are formed in the silicon oxide film 20. Subsequently, a titanium/titanium nitride film is formed on the silicon oxide film 20 including the bottom surfaces and inner walls of the contact holes 21. The titanium/titanium nitride film is formed of a multilayered film of a titanium film and a titanium nitride film, and it can be formed by, for example, sputtering. This titanium/titanium nitride film has a so-called barrier property that prevents tungsten which is a material of a film to be buried in a subsequent process from diffusing into silicon.

Subsequently, a tungsten film is formed on the entire main surface of the semiconductor substrate 1 so as to be buried in the contact holes 21. This tungsten film can be formed by using, for example, CVD. Then, an unnecessary portion of the titanium/titanium nitride film and the tungsten film formed on the silicon oxide film 20 are removed through CMP, thereby forming plugs 22.

Next, a titanium/titanium nitride film, an aluminum film, and a titanium/titanium nitride film are sequentially formed on the silicon oxide film 20 and the plugs 22. These films can be formed by, for example, sputtering. Subsequently, through the photolithography and etching processes, these films are patterned to form wires 23. Though wires are further formed on the wires 23, the description thereof is omitted here. In this manner, the semiconductor device according to the present embodiment can be formed.

In the present embodiment, as shown in FIG. 13, a heat treatment is performed after the aluminum oxide film 8 is formed on the semiconductor substrate 1. However, the process of performing a heat treatment is not restrictively performed after the aluminum oxide film 8 is formed. For example, as shown in FIG. 11, a heat treatment can be performed in a state where the hafnium oxide film 5 is exposed in the p channel MISFET formation region. Furthermore, as shown in FIG. 14, a heat treatment can be performed after the tantalum nitride film 9 is formed on the semiconductor substrate 1.

However, when a heat treatment is performed in a state where the hafnium oxide film 5 is exposed in the p channel MISFET formation region as shown in FIG. 11, a small amount of oxygen has to be supplied in order to repair defects of the hafnium oxide film 5. For this purpose, the heat treatment is performed in an atmosphere containing oxygen. However, since the resist film 7 is exposed in the n channel MISFET formation region, there is a possibility that the resist film 7 may be exposed to the atmosphere containing oxygen and damaged. By contrast, when the aluminum oxide film 8 is formed as in the present embodiment, since oxygen is supplied to the underlying hafnium oxide film from the aluminum oxide film 8, it is not necessary to use an atmosphere containing oxygen. Furthermore, even if such an atmosphere containing oxygen is used, since the aluminum oxide film 8 is formed on the resist film 7 in the n channel MISFET formation region, the resist film 7 is protected. Accordingly, it can be said that a heat treatment is desirably performed after the aluminum oxide film 8 is formed. Still further, the thermal treatment after forming the aluminum oxide film 8 is desirable because the film quality of the aluminum oxide film 8 itself can be increased and also the surface of the aluminum oxide film 8 can be cleaned.

Also, as shown in FIG. 14, it is conceivable that a heat treatment is performed after the tantalum nitride film 9 is formed. However, if the tantalum nitride film 9 is formed at a stage where a defect is present in the hafnium oxide film 5, since the hafnium oxide film 5 itself is in an unstable state, this is not desirable. Accordingly, as described in the present embodiment, it is desired to perform a heat treatment after the aluminum oxide film 8 is formed.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be widely used in manufacturing industries for manufacturing semiconductor devices.

What is claimed is:

1. A semiconductor device having a p channel MISFET in a first region of a semiconductor substrate and an n channel MISFET in a second region of the semiconductor substrate,
wherein the p channel MISFET comprises:
(a) a gate insulating film which is formed on the semiconductor substrate and is formed of a high dielectric-constant film with a dielectric constant higher than that of a silicon oxide film;
(b) an insulating metal oxide film which is formed on the gate insulating film and generates a dipole; and
(c) a gate electrode which is formed on the metal oxide film.

2. The semiconductor device according to claim 1,
wherein the gate electrode is formed of a conductive film containing metal.

3. The semiconductor device according to claim 2,
wherein the gate electrode is formed of any one of a TaN film, a TiN film, a TaSiN film, a TiAlN film, an HfN film, an NiₓSi₁₋ₓ film, a PtSi film, an NiₓTa₁₋ₓSi film, an NiₓPt₁₋ₓSi film, an HfSi film, a WSi film, an IrₓSi₁₋ₓ film, a TaGe film, a TaCₓ film, an Mo film, and a W film.

4. The semiconductor device according to claim 2,
wherein the gate electrode is formed of the conductive film having a work function value of 4.4 eV to 4.9 eV at the time of contacting a silicon oxide film.

5. The semiconductor device according to claim 1,
wherein the metal oxide film is formed of any one of an aluminum oxide film, a tantalum oxide film, a titanium oxide film, a lanthanum oxide film, and a rare-earth oxide film.

6. The semiconductor device according to claim 1,
wherein the metal oxide film is formed of an aluminum oxide film and has a film thickness of 3 angstrom or more and 12 angstrom or less.

7. The semiconductor device according to claim 1,
wherein the gate insulating film is formed of any one of a hafnium oxide film, a hafnium silicate film, a hafnium silicon oxynitride film, an aluminum oxide film, and an aluminum oxide oxynitride film.

8. The semiconductor device according to claim 1,
wherein the gate electrode has a work function value higher than a work function value when the gate electrode is formed on the gate insulating film without forming the metal oxide film.

9. The semiconductor device according to claim 1,
wherein the metal oxide film has a function to shift a work function value of the gate electrode.

10. A semiconductor device having a p channel MISFET in a first region of a semiconductor substrate and an n channel MISFET in a second region of the semiconductor substrate,
wherein the p channel MISFET comprises:
(a) a first gate insulating film which is formed on the semiconductor substrate and is formed of a high dielectric-constant film with a dielectric constant higher than that of a silicon oxide film;
(b) an insulating metal oxide film which is formed on the first gate insulating film and generates a dipole; and
(c) a first gate electrode which is formed on the metal oxide film, and
the n channel MISFET comprises:
(d) a second gate insulating film which is formed on the semiconductor substrate and is formed of a high dielectric-constant film with a dielectric constant higher than that of a silicon oxide film; and
(e) a second gate electrode which is formed on the second gate insulating film.

11. A semiconductor device manufacturing method in which a p channel MISFET is formed in a first region of a semiconductor substrate and an n channel MISFET is formed in a second region of the semiconductor substrate, the method comprising the steps of:
(a) forming a high dielectric-constant film with a dielectric constant higher than that of a silicon oxide film in the first region and the second region of the semiconductor substrate;
(b) forming a second conductive film containing metal on the high dielectric-constant film formed in the first region and the second region;
(c) removing the second conductive film formed in the first region;
(d) forming an insulating metal oxide film in the first region and the second region;
(e) performing a heat treatment to the semiconductor substrate;
(f) forming a first conductive film containing metal on the metal oxide film formed in the first region and the second region;
(g) removing the metal oxide film and the first conductive film formed in the second region and processing the high dielectric-constant film, the metal oxide film, and the first conductive film formed in the first region, thereby forming a first gate insulating film made of the high dielectric-constant film and a first gate electrode made of the first conductive film in the first region; and
(h) processing the high dielectric-constant film and the second conductive film formed in the second region, thereby forming a second gate insulating film made of the high dielectric-constant film and a second gate electrode made of the second conductive film in the second region.

12. The semiconductor device manufacturing method according to claim 11,
wherein the (e) step is performed after the (d) step and before the (f) step.

13. The semiconductor device manufacturing method according to claim 11,
wherein the metal oxide film is formed of any one of an aluminum oxide film, a tantalum oxide film, a titanium oxide film, a lanthanum oxide film, and a rare-earth oxide film.

14. The semiconductor device manufacturing method according to claim 11,
wherein the first conductive film is formed of any one of a TaN film, a TiN film, a TaSiN film, a TiAlN film, an HfN film, an NiₓSi₁₋ₓ film, a PtSi film, an NiₓTa₁₋ₓSi film, an NiₓPt₁₋ₓSi film, an HfSi film, a WSi film, an IrₓSi₁₋ₓ film, a TaGe film, a TaCₓ film, an Mo film, and a W film.

15. The semiconductor device manufacturing method according to claim 14,
wherein the second conductive film is formed of any one of an Hf film, a Ta film, an Mn film, a Y film, an La film, an Ln film, a YbSi film, a TaSi film, an ErSi film, an NiₓYb₁₋ₓSi film, and an ErGe film.
